(19) United States
(12) Patent Application Publication
(10) Pub. No.: US 2025/0374571 A1
(43) Pub. Date: Dec. 4, 2025

(54) SILICON CARBIDE METAL-OXIDE-SEMICONDUCTOR FIELD-EFFECT TRANSISTOR DEVICE AND MANUFACTURING METHOD THEREOF

(71) Applicant: Hangzhou Silicon-Magic Semiconductor Technology Co., Ltd., Hangzhou City (CN)

(72) Inventors: Hui Chen, Hangzhou City (CN); Jiakun Wang, Hangzhou City (CN)

(73) Assignee: Hangzhou Silicon-Magic Semiconductor Technology Co., Ltd., Hangzhou City (CN)

(21) Appl. No.: 19/296,571

(22) Filed: Aug. 11, 2025

Related U.S. Application Data
(62) Division of application No. 17/394,879, filed on Aug. 5, 2021.

(30) Foreign Application Priority Data
Aug. 13, 2020 (CN) 202010812855.X

(51) Int. Cl. H10D 12/01; H01L 21/04; H01L 21/76; H01L 21/761; H10D 30/66; H10D 62/10; H10D 62/17; H10D 62/832

(52) U.S. Cl. CPC H10D 12/031; H01L 21/0465; H01L 21/7602; H01L 21/761; H10D 30/665; H10D 62/107; H10D 62/393; H10D 62/8325

(57) ABSTRACT

The present disclose relates to a SiC MOSFET device and a manufacturing method thereof. The method includes providing a semiconductor base of a first doping type; forming a patterned first barrier layer on an upper surface; forming a source region extending from the upper surface to the interior of the semiconductor base by taking the first barrier layer as a mask, wherein the source region is of the first doping type; etching a part of the first barrier layer to form a second barrier layer, and allowing anion implantation window of the second barrier layer to be larger than the ion implantation window of the first barrier layer; forming a first type base region by taking the second barrier layer as a mask, wherein the first type base region is of a second doping type; and forming a contact region of the second doping type.

### CROSS-REFERENCE TO RELATED APPLICATION

This application claims priority to the Chinese Patent Application No. 202010812855.X, filed on Aug. 13, 2020 and entitled “SILICON CARBIDE METAL-OXIDE-SEMICONDUCTOR FIELD-EFFECT TRANSISTOR DEVICE AND MANUFACTURING METHOD THEREOF”, the content of which is hereby incorporated by reference in its entirety.

### BACKGROUND OF THE DISCLOSURE

### Field of Technology

The present disclosure relates to the technical field of semiconductors, in particular to a silicon carbide metal-oxide-semiconductor field-effect transistor device and manufacturing method thereof.

### Description of the Related Art

In a field of silicon carbide metal-oxide-semiconductor field-effect transistor (SIC MOSFET), in order to reduce a cell size and increase a current density of SIC MOSFET, a channel length should be set as short as possible. Taking into account an influence of lithography accuracy, the channel length less than 0.5 um will generally use a self-aligned process accomplish. Due to a low diffusion coefficient of SiC, a Si standard self-aligned process cannot be used to form the channel. The existing SIC MOSFET channel self-aligned process first uses photolithographic polysilicon as a barrier layer for a P-type base region, the polysilicon is oxidized after forming the P-type base region, a certain thickness of silicon dioxide on a surface and sidewalls of the polysilicon, and then use the silicon dioxide on the sidewalls as a barrier layer to achieve self-aligned implantation of a N+ source region. In addition, when forming a P+ contact area, since an ion implantation dose of the N+ source area is much greater than that of the P+ contact area, a separate mask is required to form a barrier layer of the P+ contact area, which increases the manufacturing cost.

On the other hand, since SiC MOSFETs are high-voltage applications, a reasonable terminal design must be used to reduce an edge electric field concentration. In the traditional design, an idea of separate design of the cell and the terminal is generally adopted, which not only increases multiple ion implantation, but also increases photolithography steps.

### SUMMARY

In order to solve the above technical problem, the present disclosure provides a silicon carbide metal-oxide-semiconductor field-effect transistor (SIC MOSFET) device and manufacturing method thereof.

According to a first aspect of the present disclosure, there is provided A manufacturing method of a SIC MOSFET device, comprising: forming a patterned first barrier layer on an upper surface of a semiconductor base with a first doping type; forming a source region with the first doping type extending form the upper surface of the semiconductor base to an interior of the semiconductor base by taking the first barrier layer as a mask; etching a part of the first barrier layer to form a second barrier layer, so that an ion implantation window of the second barrier layer is larger than an ion implantation window of the first barrier layer; forming a first type base region with a second doping type extending from the upper surface of the semiconductor base to the interior of the semiconductor base by taking the second barrier layer as a mask, and the source region is in the first type base region; and forming a contact region with the second doping type.

Preferably, the first barrier layer is etched in a thickness direction and a width direction to form the second barrier layer.

Preferably, the second barrier layer is formed by etching the first barrier layer by an isotropic etching method.

Preferably, the first barrier layer is configured as polysilicon.

Preferably, according to a channel length of a MOSFET, an etched width of the first barrier layer is controlled to form the second barrier layer.

Preferably, an etched width of the first barrier layer corresponds to a channel length of a MOSFET.

Preferably, removing the second barrier layer after forming the first type base region.

Preferably, a step of forming the contact region comprises: forming a patterned third barrier layer on the upper surface of the semiconductor base, forming the contact region extending from the upper surface of the semiconductor base to the interior of the semiconductor base by taking the third barrier layer as a mask, wherein the source region is on both sides of the contact region and adjacent to the contact region.

Preferably, further comprises: forming a second type base region extending from the upper surface of the semiconductor base to the interior of the semiconductor base before forming the contact region, the first type base region is on both sides of the second type base region and adjacent to the second type base region.

Preferably, a step of forming the second type base region comprises: forming a patterned fourth barrier layer on the upper surface of the semiconductor base; forming the second type base region with the second doping type by taking the fourth barrier layer as a mask, wherein the contact region is in the second type base region.

Preferably, a side wall is formed on a sidewall of the fourth barrier layer to form the third barrier layer.

Preferably, wherein a step of forming the side wall comprises: depositing a semiconductor layer on an upper surface of the fourth barrier layer and the upper surface of the semiconductor base; etching the semiconductor layer by an anisotropic etching method; the semiconductor layer on the sidewall of the fourth barrier layer is retained to form the side wall.

Preferably, further comprises: forming a shallow field limiting ring in a terminal region of a MOSFET device when forming the contact region, the shallow field limiting ring is of the second doping type and has a same junction depth with the contact region.

Preferably, further comprises: forming a deep field limiting ring in the terminal region of the MOSFET device when forming the second type base region, the deep field limiting ring is of the second doping type and has a same junction depth with the second type base region, wherein the shallow field limiting ring is located in the deep field limiting ring.

Preferably, a junction depth of the second type base region is not greater than a junction depth of the first type base region.

Preferably, a doping concentration of the second type base region is equal to a doping concentration of the first type base region.

Preferably, a junction depth of the contact region is not less than a junction depth of the source region, and is less than a junction depth of the first type base region.

Preferably, further comprises: removing the third barrier layer; forming a gate dielectric layer on the upper surface of the semiconductor base; forming a gate conductor layer on the gate dielectric layer; depositing an interlayer dielectric layer on the gate dielectric layer and the gate conductor layer; etching the interlayer dielectric layer to form an opening that expose an upper surface of the contact area and part of the source area; forming a source metal in the opening, and forming a drain metal on a back surface of the semiconductor base.

Preferably, the fourth barrier layer and the side wall is configured as polysilicon.

According to a second aspect of the present disclosure, there is provided SiC MOSFET device, comprising: a semiconductor base with a first doping type; a contact region with the second doping type extending form an upper surface of the semiconductor base to an interior of the semiconductor base; a source region with the first doping type extending form the upper surface of the semiconductor base to the interior of the semiconductor base and located on both sides of the contact region; a base region surrounding the contact region and the source region and including a first type base region and a second type base region; wherein the contact area is located in the second type base region, the first type base region is on both sides of the second type base region and adjacent to the second type base region.

Preferably, a junction depth of the contact region is not less than a junction depth of the source region.

Preferably, a junction depth of the second type base region is not greater than a junction depth of the first type base region.

Preferably, a width of the contact region is not greater than a width of the second type base region.

Preferably, further comprises a field limiting ring in a terminal region of a MOSFET device.

Preferably, the field limiting ring includes a shallow field limiting ring and a deep field limiting ring.

Preferably, the deep field limiting ring has a same junction depth and a same doping concentration with the second type base region.

Preferably, the shallow field limiting ring has a same junction depth and a same doping concentration with the contact region.

Preferably, a doping concentration of the second type base region is equal to a doping concentration of the first type base region.

Preferably, wherein further comprises: a gate dielectric layer and a gate conductor layer on the upper surface of the semiconductor base; an interlayer dielectric layer on the gate dielectric layer and the gate conductor layer, the an interlayer dielectric layer has an opening that expose an upper surface of the contact area and part of the source area; a source metal in contact with the source region and the contact region through the opening; and a drain metal on a back surface of the semiconductor base.

Preferably, the first doping type is one of N-type of P-type, and the second doping type is another of N-type or P-type.

According to the SIC MOSFET device and the manufacturing method thereof provided in the present disclosure, on the one hand, forming the source region and the first type base region respectively before and after the mask is etched to form the channel by use of the difference in the width of the mask before and after the mask is isotropically etched. Above method can form the short channel, reduce the on-state resistance, and make the channel distribution in the cell symmetrical to improve reliability. On the other hand, the side wall is formed by deposition and etching, and two ion implantations are performed before and after the side wall is formed to form the heavily doped contact region on the surface and the lightly doped second type base region at the bottom. The heavily doped contact region is completely covered by the lightly doped second type base region. This doping distribution not only satisfies a P+ ohmic contact, but also serves as the field limiting ring in the terminal region to play a role of voltage divider. While simplifying the process and saving costs, it can also improve breakdown characteristics and reliability of the device.

### BRIEF DESCRIPTION OF THE DRAWINGS

The above and other objectives, features and advantages of the present disclosure will become more apparent from the description of embodiments of the present disclosure below with reference to the accompanying drawings.

FIG. 1A-1F shows sectional structural schematic diagrams of various stages of a manufacturing method of a SiC MOSFET according to an embodiment of the present disclosure.

### DETAILED DESCRIPTION OF THE DISCLOSURE

Various embodiments of the present disclosure will be described in more detail below with reference to the accompanying drawings. In the various accompanying drawings, the same elements are denoted by the same or similar reference numerals. For the sake of clarity, the various portions in the accompanying drawings are not drawn to scale. In addition, some well-known portions may not be shown. For simplicity, a semiconductor structure obtained after several steps may be described in one figure.

During description of the structure of a device, when a layer or a region is called “on” or “above” another layer or another region, it may be directly on another layer or another region, or other layers or regions are included between it and another layer or another region. In addition, if the device is turned over, the layer and the region will be located “under” or “below” another layer and another region.

In order to describe the situation of being directly on another layer and another region, the specification uses the expression of “A is directly on B” or “A is on B and adjacent to B”. In the present application, “A is directly located in B” means that A is located in B, and A is directly adjacent to B, rather than that A is located in a doped region formed in B.

In the present application, the term “semiconductor structure” refers to the general name of the whole semiconductor structure formed in each step of manufacturing a semiconductor device, including all layers or regions that have been formed. The term “laterally extending” means extending in a direction substantially perpendicular to a depth direction of a trench.

In the following, many specific details of the present disclosure are described. such as the structure, material, size, processing technology and technology of the device, in order to understand the present disclosure more clearly. However, as those skilled in the art can understand, the present disclosure may not be implemented according to these specific details.

Unless specifically indicated hereinafter, various layers or regions of the semiconductor device may be composed of materials known to those skilled in the art. Semiconductor materials include, for example, group III-V semiconductors such as gallium arsenide (GaAs), indium phosphide (InP), gallium nitride (GaN) and silicon carbide (SiC), and group IV semiconductors such as silicon (Si) and germanium (Ge). A gate conductor and electrode layer may be made from various conductive materials, such as metal layers, doped gate conductor layers, or stacked gate conductors including the metal layer and the doped gate conductor layer, or other conductive materials, such as tantalum carbide (TaC), titanium nitride (TiN), TaSiN, HfSiN, titanium nitride silicon (TiSiN), titanium carbonitride (TiCN), TaAlC, titanium aluminium nitride (TiAlN), tantalum mononitride (TaN), PtSix, Ni3Si, platinum (Pt), ruthenium (Ru), wolfram (W), and the various conductive materials. A gate dielectric layer may be composed of Silicon Oxide (SiO2) or a material with a dielectric constant greater than SiO2, such as oxides, nitrides, oxynitrides, silicates, aluminates, and titanates. In addition, the gate dielectric layer may not only be formed of materials known to those skilled in the art, but also materials developed for gate dielectrics in the future may be used.

The present disclosure provides A manufacturing method of a SiC MOSFET device, comprising: providing a semiconductor base with a first doping type; forming a patterned first barrier layer on an upper surface of the semiconductor base; forming a source region with the first doping type extending form the upper surface of the semiconductor base to an interior of the semiconductor base by taking the first barrier layer as a mask; etching a part of the first barrier layer to form a second barrier layer, so that an ion implantation window of the second barrier layer is larger than an ion implantation window of the first barrier layer; forming a first type base region with a second doping type extending from the upper surface of the semiconductor base to the interior of the semiconductor base by taking the second barrier layer as a mask, and the source region is in the first type base region; and forming a contact region with the second doping type.

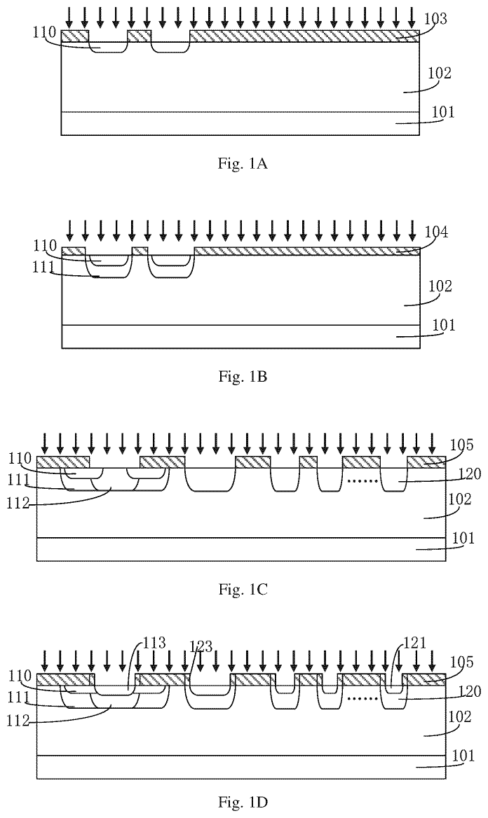

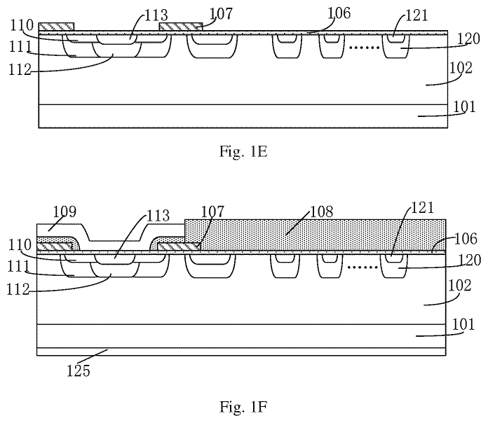

FIG. 1A-1F shows sectional structural schematic diagrams of various stages of the manufacturing method of the SiC MOSFET according to an embodiment of the present disclosure.

As shown in FIG. 1A, a semiconductor base with a first doping type is provided, and a patterned first barrier layer 103 is formed on an upper surface of the semiconductor base; then by taking the first barrier layer 103 as a mask, a source region 110 with the first doping type extending form the upper surface of the semiconductor base to an interior of the semiconductor base is formed through a first ion implantation process. Wherein said first barrier layer 103 is configured as polysilicon. Specifically, a layer of polysilicon is deposited on the upper surface of the semiconductor base and etched to form the first barrier layer 103 with an ion implantation window. The ion implantation window of the first barrier layer 103 corresponds to a position of the source region 110. In this embodiment, the semiconductor base includes a semiconductor substrate 101 of the first doping type and an epitaxial layer 102 of the first doping type on the semiconductor substrate 101, that is, the first barrier layer 103 is formed on an upper surface of the epitaxial layer 102. A lower surface of the epitaxial layer 102 is in contact with the semiconductor substrate 101, and the upper surface of the epitaxial layer 102 is opposite to the lower surface of the epitaxial layer 102. Of course, the first barrier layer 103 is not limited to the polysilicon described in this disclosure, and those skilled in the art can also choose other materials that are different from the semiconductor base and can be used as a mask.

As shown in FIG. 1B, etching a part of the first barrier layer 103 to form a second barrier layer 104, so that an ion implantation window of the second barrier layer 104 is larger than an ion implantation window of the first barrier layer 103; by taking the second barrier layer 104 as a mask, a first type base region 111 with a second doping type extending from the upper surface of the semiconductor base to the interior of the semiconductor is formed through a second ion implantation process, and the source region 110 is located in the first type base region 111. The ion implantation window of the second barrier layer 104 corresponds to a position of the first type base region 111. Specifically, the first barrier layer 103 is etched in a thickness direction and a width direction to form the second barrier layer 104, so that the ion implantation window of the second barrier layer 104 is greater and the thickness of the second barrier layer 104 is less relative to the first barrier layer 103. Specifically, the first barrier layer 103 is etched in an isotropic etching manner to form the second barrier layer 104. In this embodiment, according to a channel length of the MOSFET, an etched width of the first barrier layer is controlled to form the second barrier layer. Specifically, the etched width of the first barrier layer corresponds to the channel length, furthermore, the etched width of the first barrier layer is the same with the channel length.

Of course, those skilled in the art can also use other etching methods to form the second barrier layer, or just etch the width of the first barrier layer to make the ion implantation window wider to form the second barrier layer. This does not impose any restrictions.

After forming the first type base region 111, the second barrier layer 104 is removed.

Subsequently, forming a patterned third barrier layer on the upper surface of the semiconductor base, forming the contact region extending from the upper surface of the semiconductor base to the interior of the semiconductor base by taking the third barrier layer as a mask, wherein the source region is on both sides of the contact region and adjacent to the contact region. Before forming the contact region, the manufacturing method further comprises: forming a second type base region extending from the upper surface of the semiconductor base to the interior of the semiconductor base, the first type base region is on both sides of the second type base region and adjacent to the second type base region. Wherein, a step of forming the second type base region comprises: forming a patterned fourth barrier layer on the upper surface of the semiconductor base; forming the second type base region with the second doping type by taking the fourth barrier layer as a mask, wherein the contact region is in the second type base region. A side wall is formed on a sidewall of the fourth barrier layer to form the third barrier layer.

Specifically, as shown in FIG. 1C, forming the patterned fourth barrier layer 105 on the upper surface of the semiconductor base, by taking the fourth barrier layer 105 as a mask, the second type base region 112 with the second doping type extending from the upper surface of the semiconductor base to the interior of the semiconductor base is formed through a third ion implantation process. The fourth barrier layer 105 is configured as polysilicon. Specifically, a step of forming the fourth barrier layer 105 includes: a polysilicon layer is deposited on the upper surface of the semiconductor base and etched to form a fourth barrier layer 105 having an ion implantation window, and the ion implantation window of the fourth barrier layer 105 corresponds to a position of the second type base region 112. The first type base region 111 is on both sides of the second type base region 112 and adjacent to second type base region 112, and a junction depth of the second type base region 112 is not greater than a junction depth of the first type base region 111. Preferably, the junction depth of the second type base region 112 is equal to the first type base region 111. A doping concentration of the second type base region 112 is equal to a doping concentration of the first type base region 111.

Further, when forming the second type base region 112, a deep field limiting ring 120 is formed in a terminal region of the MOSFET device, that is, the second type base region 112 and the deep field limiting ring 120 is formed in a same ion implantation process (the third ion implantation process). The second type base region 112 has a same doping concentration and a same junction depth with the deep field limiting ring.

The MOSFET includes an active region and the terminal region, the active region includes the source region 110, the first type base region 111 and the contact region subsequently formed, and the terminal region includes the deep field limiting ring 120 and a shallow field limiting ring subsequently formed. It should be noted that in a direction away from the active region, widths of the deep field limiting rings can be set to decrease sequentially; or in the direction away from the active region, gaps between the deep field limiting rings can be set to increase sequentially. Of course, the width of the deep field limiting ring and the gap between the deep field limiting rings can be actually arranged and adjusted according to actual needs, such as the breakdown voltage of the MOSFET, etc., and is not limited to this.

As shown in FIG. 1D, a side wall 123 is formed on a sidewall of the fourth barrier layer 105 to form the third barrier layer. Then by taking the third barrier layer as a mask, the contact region 113 with the second doping type is formed extending from the upper surface of the semiconductor base to the interior of the semiconductor base is formed through a fourth ion implantation process. Wherein, the source region 110 is on both sides of the contact region 113 and adjacent to the contact region 113, the contact region 113 is located in the source region 110. A doping concentration of the contact region 113 is greater than the doping concentration of the first type base region 111 and the doping concentration of the second type base region 112. A junction depth of the contact region 113 is not less than that of the source region 110, and is less than that of the second type base region 112. Specifically, a step of forming the side wall 123 includes: depositing a semiconductor layer on an upper surface of the fourth barrier layer 105 and the upper surface of the semiconductor base etching the semiconductor layer by an anisotropic etching method; the semiconductor layer on the sidewall of the fourth barrier layer is retained to form the side wall 123. The side wall 123 can also be formed by other methods, which is not limited here. Wherein, the semiconductor layer is configured as polysilicon.

Further, when forming the contact region 113, a shallow field limiting ring 121 is formed in the terminal region of the MOSFET device, that is, the contact region 113 and the shallow field limiting ring 121 is formed in a same ion implantation process (the fourth ion implantation process). The ion implantation window of the third barrier layer corresponds to a position of the shallow field limiting ring 121. The contact region 113 has a same doping concentration and a same junction depth with shallow field limiting ring 121.

Removing the third barrier layer after forming the contact region and the shallow field limiting ring.

As shown in FIG. 1E, forming a gate dielectric layer 106 on the upper surface of the semiconductor base, and forming a gate conductor layer 107 on the gate dielectric layer. Specifically, the gate dielectric layer 106 can be formed by a thermal oxidation process, and the gate dielectric layer 106 is an oxide layer. A step of forming the gate conductor layer 107 includes: depositing a polysilicon layer on the gate dielectric layer 106, removing the polysilicon layer above the contact region, a part of the terminal region and a part of the source region by a retching process. Of course, the gate conductor layer can also be made of other materials, which is not limited here.

As shown in FIG. 1F, depositing an interlayer dielectric layer 108 on the gate dielectric layer and the gate conductor layer; etching the interlayer dielectric layer 108 to form an opening that expose an upper surface of the contact area 113 and part of the source area 110; forming a source metal 109 in the opening, and forming a drain metal 125 on a back surface of the semiconductor base. Specifically, a step of forming the opening includes: using a mask to shield the interlayer dielectric layer above the terminal region, etching the interlayer dielectric layer above the active region to expose the contact area 113 and part of the source area 11, and the interlayer dielectric layer 108 remains on the upper surface and sidewalls of the gate conductor 107.

Wherein, the first doping type is one of N-type or P-type, and the second doping type is another of N-type or P-type.

The present disclosure further provides a SiC MOSFET device, includes: a semiconductor base with a first doping type; a contact region with the second doping type extending form an upper surface of the semiconductor base to an interior of the semiconductor base; a source region with the first doping type extending form the upper surface of the semiconductor base to the interior of the semiconductor base and located on both sides of the contact region; a base region surrounding the contact region and the source region and including a first type base region and a second type base region; wherein the contact area is located in the second type base region, the first type base region is on both sides of the second type base region and adjacent to the second type base region.

As shown in FIG. 1F, the SiC MOSFET device includes the semiconductor base with the first doping type. In this embodiment, the semiconductor base includes the semiconductor substrate 101 of the first doping type and the epitaxial layer 102 of the first doping type on the semiconductor substrate.

The SiC MOSFET device further includes the contact region 113 with the second doping type extending form the upper surface of the epitaxial layer 102 to the interior of the epitaxial layer 102; the source region 110 with the first doping type extending form the upper surface of the epitaxial layer 102 to the interior of the epitaxial layer 102; the base region surrounding the contact region 113 and the source region 110 and including the first type base region 111 and the second type base region 112; wherein the contact region 113 is located in the second type base region 112, and the first type base region 111 is on both sides of the second type base region 112 and adjacent to the second type base region 112. The junction depth of the contact region 113 is not less than the junction depth of the source region 110, and the junction depth of the second type base region 112 is not greater than the junction depth of the first type base region 111. Preferably, the junction depth of the second type base region 112 is equal to the junction depth of the first type base region 111. The width of the contact region 113 is not greater than the width of the second type base region 112, and the width of the first type base region 111 is greater than the width of the source region 110. The doping concentration of the second type base region 112 is equal to the doping concentration of the first type base region 111.

Further, the SiC MOSFET further includes the field limiting ring in the terminal region of the MOSFET device. The field limiting ring includes the deep field limiting ring 120 and the shallow field limiting ring 121, and the shallow field limiting ring 121 is located in the deep field limiting ring 120. The deep field limiting ring 120 has the same junction depth and the same doping concentration with the second type base region 112. The shallow field limiting ring 121 has the same junction depth and the same doping concentration with the contact region 113.

It should be noted that in the direction away from the active region, widths of the deep field limiting rings can be set to decrease sequentially; or in the direction away from the active region, gaps between the deep field limiting rings can be set to increase sequentially. Of course, the width of the deep field limiting ring and the gap between the deep field limiting rings can be actually arranged and adjusted according to actual needs, such as the breakdown voltage of the MOSFET, etc., and is not limited to this.

Further, the SiC MOSFET device further includes: the gate dielectric layer 106 and the gate conductor layer 107 on the upper surface of the semiconductor base; the interlayer dielectric layer 108 on the gate dielectric layer 106 and the gate conductor layer 107, the interlayer dielectric layer 108 has the opening that expose the upper surface of the contact region 113 and part of the source region 110; the source metal 109 in contact with the source region 110 and the contact region 113 through the opening; and the drain metal 125 on the back surface of the semiconductor base. Wherein, the gate conductor layer 107 is located above the gate dielectric layer 106, the gate conductor layer is located above channel of the SiC MOSFET device. A part of the interlayer dielectric layer 108 on the active region of the SiC MOSFET device is etched to form the opening, and the interlayer dielectric layer 108 remaining on the active region of the SiC MOSFET device covers the upper surface and sidewalls of the gate conductor layer 109.

Preferably, the first doping type is one of N-type or P-type, and the second doping type is another of N-type or P-type.

According to the SiC MOSFET device and the manufacturing method thereof provided in the present disclosure, on the one hand, forming the source region and the first type base region respectively before and after the mask is etched to form the channel by use of the difference in the width of the mask before and after the mask is isotropically etched. Above method can form the short channel, reduce the on-state resistance, and make the channel distribution in the cell symmetrical to improve reliability. On the other hand, the side wall is formed by deposition and etching, and two ion implantations are performed before and after the side wall is formed to form the heavily doped contact region on the surface and the lightly doped second type base region at the bottom. The heavily doped contact region is completely covered by the lightly doped second type base region. This doping distribution not only satisfies a P+ ohmic contact, but also serves as the field limiting ring in the terminal region to play a role of voltage divider. While simplifying the process and saving costs, it can also improve breakdown characteristics and reliability of the device.

It should be noted that in this context, the terms “comprising”, “including” or any other variant thereof are intended to cover non-exclusive inclusion, such that a process, a method, an article or a device including a series of elements include those elements, but include other elements not listed clearly, or further include elements inherent to such process, method, article or device. In the case of no more limitations, the element limited by the sentence “comprising a . . . ” does not exclude that there exists another same element in the process, method, article or device comprising the element.

According to the embodiments of the present disclosure described above, these embodiments do not describe all the details in detail, nor do they limit the present disclosure to only the specific embodiments described. Obviously, according to the above description. many modifications and changes can be made. This specification selects and specifically describes these embodiments in order to better explain the principles and practical applications of the present disclosure, so that those skilled in the art can make good use of the present disclosure and make modifications based on the present disclosure. The present disclosure is only limited by the claims and their full scope and equivalents.

What is claimed is:

1. A manufacturing method of a SIC MOSFET device, comprising:
forming a patterned first barrier layer on an upper surface of a semiconductor base with a first doping type;
forming a source region with said first doping type extending form said upper surface of said semiconductor base to an interior of said semiconductor base by taking said first barrier layer as a mask;
etching a part of said first barrier layer to form a second barrier layer, so that an ion implantation window of said second barrier layer is larger than an ion implantation window of said first barrier layer;
forming a first type base region with a second doping type extending from said upper surface of said semiconductor base to said interior of said semiconductor base by taking said second barrier layer as a mask, and said source region is in said first type base region; and
forming a contact region with said second doping type.

2. The manufacturing method according to claim 1, wherein said first barrier layer is etched in a thickness direction and a width direction to form said second barrier layer.

3. The manufacturing method according to claim 1, wherein said second barrier layer is formed by etching said first barrier layer by an isotropic etching method.

4. The manufacturing method according to claim 1, wherein said first barrier layer is configured as polysilicon.

5. The manufacturing method according to claim 1, wherein according to a channel length of a MOSFET, an etched width of said first barrier layer is controlled to form said second barrier layer.

6. The manufacturing method according to claim 1, wherein an etched width of said first barrier layer corresponds to a channel length of a MOSFET.

7. The manufacturing method according to claim 1, wherein removing said second barrier layer after forming said first type base region.

8. The manufacturing method according to claim 7, wherein a step of forming said contact region comprises:
forming a patterned third barrier layer on said upper surface of said semiconductor base,
forming said contact region extending from said upper surface of said semiconductor base to said interior of said semiconductor base by taking said third barrier layer as a mask,
wherein said source region is on both sides of said contact region and adjacent to said contact region.

9. The manufacturing method according to claim 8, wherein further comprises: forming a second type base region extending from said upper surface of said semiconductor base to said interior of said semiconductor base before forming said contact region, said first type base region is on both sides of said second type base region and adjacent to said second type base region.

10. The manufacturing method according to claim 9, wherein a step of forming said second type base region comprises:
forming a patterned fourth barrier layer on said upper surface of said semiconductor base;
forming said second type base region with said second doping type by taking said fourth barrier layer as a mask,
wherein said contact region is in said second type base region.

11. The manufacturing method according to claim 10, wherein a side wall is formed on a sidewall of said fourth barrier layer to form said third barrier layer.

12. The manufacturing method according to claim 11, wherein a step of forming said side wall comprises:
depositing a semiconductor layer on an upper surface of said fourth barrier layer and said upper surface of said semiconductor base;
etching said semiconductor layer by an anisotropic etching method;
said semiconductor layer on said sidewall of said fourth barrier layer is retained to form said side wall.

13. The manufacturing method according to claim 9, wherein further comprises: forming a shallow field limiting ring in a terminal region of a MOSFET device when forming said contact region, said shallow field limiting ring is of said second doping type and has a same junction depth with said contact region.

14. The manufacturing method according to claim 13, wherein further comprises: forming a deep field limiting ring in said terminal region of said MOSFET device when forming said second type base region, said deep field limiting ring is of said second doping type and bas a same junction depth with said second type base region, wherein said shallow field limiting ring is located in said deep field limiting ring.

15. The manufacturing method according to claim 9, wherein a junction depth of said second type base region is not greater than a junction depth of said first type base region.

16. The manufacturing method according to claim 9, wherein a doping concentration of said second type base region is equal to a doping concentration of said first type base region.

17. The manufacturing method according to claim 1, wherein a junction depth of said contact region is not less than a junction depth of said source region, and is less than a junction depth of said first type base region.

18. The manufacturing method according to claim 8, wherein further comprises:
removing said third barrier layer;
forming a gate dielectric layer on said upper surface of said semiconductor base;
forming a gate conductor layer on said gate dielectric layer;
depositing an interlayer dielectric layer on said gate dielectric layer and said gate conductor layer;
etching said interlayer dielectric layer to form an opening that expose an upper surface of said contact area and part of said source area;
forming a source metal in said opening, and forming a drain metal on a back surface of said semiconductor base.

19. The manufacturing method according to claim 11, wherein said fourth barrier layer and said side wall is configured as polysilicon.

20. A SIC MOSFET device, comprising:
a semiconductor base with a first doping type;
a contact region with said second doping type extending form an upper surface of said semiconductor base to an interior of said semiconductor base;
a source region with said first doping type extending form said upper surface of said semiconductor base to said interior of said semiconductor base and located on both sides of said contact region;
a base region surrounding said contact region and said source region and including a first type base region and a second type base region;
wherein said contact area is located in said second type base region, said first type base region is on both sides of said second type base region and adjacent to said second type base region.

21. The SiC MOSFET device according to claim 20, wherein a junction depth of said contact region is not less than a junction depth of said source region.

22. The SiC MOSFET device according to claim 20, wherein a junction depth of said second type base region is not greater than a junction depth of said first type base region.

23. The SiC MOSFET device according to claim 20, wherein a width of said contact region is not greater than a width of said second type base region.

24. The SiC MOSFET device according to claim 20, wherein further comprises a field limiting ring in a terminal region of a MOSFET device.

25. The SiC MOSFET device according to claim 24, wherein said field limiting ring includes a shallow field limiting ring and a deep field limiting ring.

26. The SIC MOSFET device according to claim 25, wherein said deep field limiting ring has a same junction depth and a same doping concentration with said second type base region.

27. The SiC MOSFET device according to claim 25, wherein said shallow field limiting ring has a same junction depth and a same doping concentration with said contact region.

28. The SiC MOSFET device according to claim 20, wherein a doping concentration of said second type base region is equal to a doping concentration of said first type base region.

29. The SiC MOSFET device according to claim 20, wherein further comprises:
a gate dielectric layer and a gate conductor layer on said upper surface of said semiconductor base;
an interlayer dielectric layer on said gate dielectric layer and said gate conductor layer, said an interlayer dielectric layer has an opening that expose an upper surface of said contact area and part of said source area;
a source metal in contact with said source region and said contact region through said opening; and
a drain metal on a back surface of said semiconductor base.

30. The SiC MOSFET device according to claim 20, wherein said first doping type is one of N-type or P-type, and said second doping type is another of N-type or P-type.
